(19) United States
(12) Patent Application Publication
(10) Pub. No.: US 2025/0167109 A1
(43) Pub. Date: May 22, 2025

(54) STACKED SEMICONDUCTOR STRUCTURES INCLUDING A PASSIVE DEVICE

(71) Applicant: GlobalFoundries Singapore Pte. Ltd., Singapore (SG)

(72) Inventor: ANTHONY JEREMY VILLALON, Singapore (SG)

(21) Appl. No.: 18/513,983

(22) Filed: Nov. 20, 2023

(51) Int. Cl. H01L 23/528; H01L 21/768; H01L 23/522

(52) U.S. Cl. CPC H01L 23/5283; H01L 21/76898; H01L 23/5226

(57) ABSTRACT

The embodiments herein relate to stacked semiconductor structures including a passive device and methods of forming the same. A semiconductor structure is provided. The semiconductor structure includes a substrate, a first active layer, a second active layer, a first interconnection structure, a second interconnection structure, a first interlayer dielectric stack, and a passive device. The first active layer is in the substrate and the second active layer is vertically over the first active layer. The first interconnection structure is between the first active layer and the second active layer. The second interconnection structure is between the first interconnection structure and the second active layer. The first interlayer dielectric stack is between the first interconnection structure and the second interconnection structure. The passive device is in the first interlayer dielectric stack.

### TECHNICAL FIELD

The present disclosure relates generally to semiconductor devices, and more particularly to stacked semiconductor structures including a passive device and methods of forming the same.

### BACKGROUND

The proliferation of connected devices has driven the need for smaller form factors, higher electrical performances, and/or increased thermal performance in semiconductor technology. Semiconductor devices may be stacked using various techniques like wafer stacking, die stacking, and through-substrate vias (TSVs). Such three-dimensional (3D) integration of semiconductor devices may deliver homogenously and heterogeneously compact assemblies.

However, the use of TSVs may inadvertently introduce undesirable parasitic electrical components, such as resistance and capacitance, due to the substantial size of TSV structures, which can negatively impact signal propagation and overall device performance.

Therefore, in order to improve the device performance, stacked semiconductor structures including a passive device and methods of forming the same are provided to overcome, or at least ameliorate, the disadvantages described above.

### SUMMARY

To achieve the foregoing and other aspects of the present disclosure, stacked semiconductor structures including a passive device and methods of forming the same are presented.

According to an aspect of the present disclosure, a semiconductor structure is provided. The semiconductor structure includes a substrate, a first active layer, a second active layer, a first interconnection structure, a second interconnection structure, a first interlayer dielectric stack, and a passive device. The first active layer is in the substrate and the second active layer is vertically over the first active layer. The first interconnection structure is between the first active layer and the second active layer. The second interconnection structure is between the first interconnection structure and the second active layer. The first interlayer dielectric stack is between the first interconnection structure and the second interconnection structure. The passive device is in the first interlayer dielectric stack.

According to another aspect of the present disclosure, a method of forming a semiconductor structure is provided. The method includes forming a first semiconductor device, a second semiconductor device, and a third semiconductor device. The first semiconductor device includes a substrate, a first active layer in the substrate, a first interconnection structure over the first active layer, and a first conductive plug over the first interconnection structure. The second semiconductor device includes a passive device, a second interconnection structure over the passive device, and a second conductive plug over the second interconnection structure. The third semiconductor device includes a second active layer, a third interconnection structure over the second active layer, and a third conductive plug over the third interconnection structure. The third semiconductor device is bonded between the first semiconductor device and the second semiconductor device, such that the passive device in the second semiconductor device is arranged between and electrically connected to the first interconnection structure and the second interconnection structure.

### BRIEF DESCRIPTION OF THE DRAWINGS

The embodiments of the present disclosure will be better understood from a reading of the following detailed description, taken in conjunction with the accompanying drawings:

FIG. 1 is a cross-sectional view of a semiconductor device, according to an embodiment of the disclosure.

FIG. 2 is a cross-sectional view of another semiconductor device, according to an embodiment of the disclosure.

FIG. 3 is a cross-sectional view of yet another semiconductor device, according to an embodiment of the disclosure.

FIGS. 4A to 4D are cross-sectional views, depicting successive stages of manufacturing a stacked semiconductor structure, and FIG. 4D(a) illustrates a cross-sectional view of an enlarged portion of the stacked semiconductor structure in FIG. 4D, according to an embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the disclosure.

Additionally, features in the drawings are not necessarily drawn to scale. For example, the dimensions of some of the features in the drawings may be exaggerated relative to other features to help improve the understanding of the embodiments of the device. The same reference numerals in different drawings denote the same features, while similar reference numerals may, but do not necessarily, denote similar features.

### DETAILED DESCRIPTION

The present disclosure relates to stacked semiconductor structures including a passive device and methods of forming the same. As used herein, the term “stacked semiconductor structures” refers to semiconductor devices that are stacked on each other by wafer-to-wafer bonding, die-to-wafer bonding, or die-to-die bonding.

The semiconductor devices described herein may be manufactured in a number of ways using a number of different tools, and are formed with dimensions per their intended design. Generally, methodologies and tools employed to manufacture semiconductor devices have been adopted from known semiconductor technologies. For example, semiconductor devices are manufactured by building electronic components (e.g., transistors, capacitors, interconnection structures, etc.) on bulk or composite semiconductor substrates.

Various embodiments of the present disclosure are now described in detail with accompanying drawings. It is noted that like and corresponding features are referred to by the use of the same reference numerals. The embodiments disclosed herein are exemplary, and not intended to be exhaustive or limiting to the disclosure.

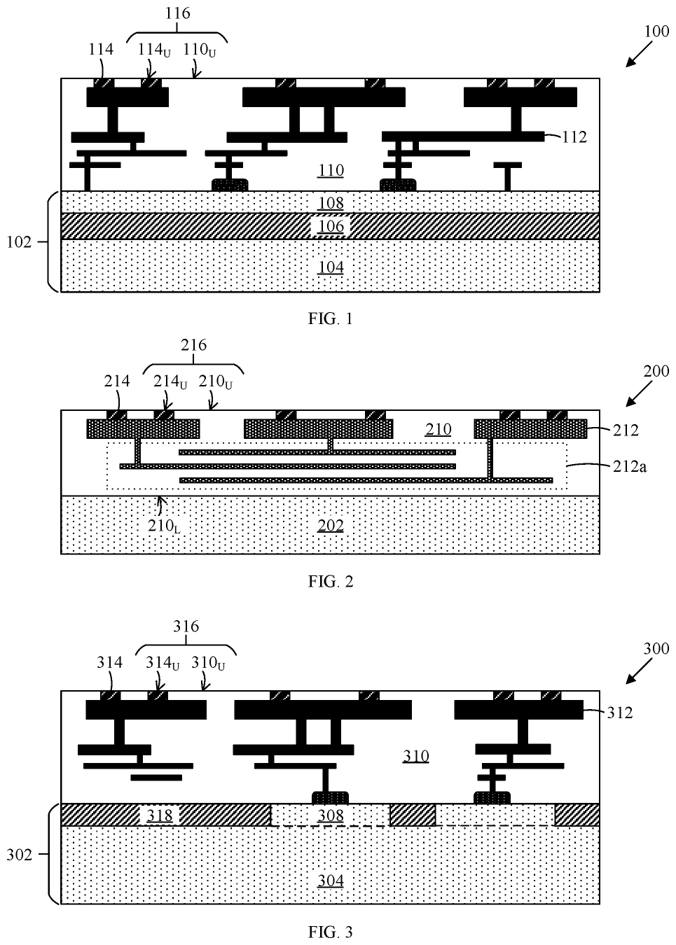

FIGS. 1 through 3 illustrate various elements for manufacturing a stacked semiconductor structure. FIG. 1 is a cross-sectional view of a semiconductor device 100, according to an embodiment of the disclosure. The semiconductor device 100 may be in wafer or die form. The semiconductor device 100 may include a substrate 102. For purposes of description, the substrate 102 is illustrated and described as a composite semiconductor substrate, such as a semiconductor-on-insulator (SOI) substrate. The substrate 102 may include a base substrate layer 104, a buried insulator layer 106 over the base substrate layer 104, and a semiconductor layer 108 over the buried insulator layer 106. The semiconductor layer 108 may sometimes be referred to as an SOI layer, a device layer, or an active layer. Even though FIG. 1 illustrates the semiconductor layer 108 as a continuous layer having a uniform thickness, the semiconductor layer 108 may be discontinuous and/or have varying thicknesses in some embodiments. The base substrate layer 104 and the semiconductor layer 108 may include a semiconductor material, for example, silicon, silicon germanium, silicon carbide, or other II-VI or III-V semiconductor compounds, though not necessarily the same semiconductor material. The semiconductor layer 108 may be doped while the base substrate layer 104 may be undoped or doped to a dopant concentration lower than the semiconductor layer 108. The buried insulator layer 106 may include an electrically insulative material, for example, silicon dioxide or aluminum oxide, and may sometimes be referred to as a buried oxide (BOX) layer. Alternatively, the substrate 102 may be a bulk semiconductor substrate.

The semiconductor device 100 may further include an interlayer dielectric stack 110 over the substrate 102 and one or more electronic components 112 within the interlayer dielectric stack 110. The electronic components 112 may include active devices and interconnection structures in the form of electrically conductive lines and vias structures. The active devices may have the ability to control the electrical current and may include transistors, triode vacuum tubes (valves), and tunnel diodes. The electronic components 112 may, additionally or optionally, include passive devices. The passive devices may be incapable of controlling electrical current by means of another electrical signal and may include resistors, capacitors, and inductors. Passive devices generally function by receiving an electric charge through the interconnection structures.

The interlayer dielectric stack 110 may be formed from a plurality of dielectric layers (not shown) and include an upper dielectric surface 110_{U}. The interlayer dielectric stack 110 may include an electrically insulative material, for example, silicon dioxide, carbon-doped silicon oxide, tetraethoxysilane (TEOS), borophosphosilicate glass (BPSG), or undoped silicate glass (USG).

The semiconductor device 100 may further include conductive plugs 114 within the interlayer dielectric stack 110. The conductive plugs 114 may be arranged over and electrically connected to the electronic components 112, such as the interconnection structures. The conductive plugs 114 may serve as bonding structures to other wafers and/or dies for a stacked structure. The conductive plugs 114 may include a metallic material, for example, copper, aluminum, or alloys thereof. The conductive plugs 114 may include an upper conductive surface 114_{U}, and the upper conductive surfaces 114_{U} of the conductive plugs 114 and the upper dielectric surface 110_{U} of the interlayer dielectric stack 110 may define a stacking interface 116, upon which other wafers and/or dies may be stacked on the semiconductor device 100. Even though FIG. 1 illustrates the upper dielectric surface 110_{U} and the upper conductive surfaces 114_{U} to be substantially coplanar, the upper conductive surfaces 114_{U} of the conductive plugs 114 may be dished below the upper dielectric surface 110_{U}. Although FIG. 1 only illustrates four conductive plugs 114, the number of conductive plugs 114 may vary according to the design requirements of the stacked semiconductor structure that will be ultimately formed using the semiconductor device 100.

The electronic components 112 and the interlayer dielectric stack 110 may be formed by a plurality of techniques, at least including deposition techniques, patterning, and planarization techniques. Deposition techniques refer to the process of applying a material over another material. Exemplary deposition techniques may include spin-on coating, sputtering, chemical vapor deposition (CVD), physical vapor deposition (PVD), molecular beam deposition (MBD), pulsed laser deposition (PLD), liquid source misted chemical deposition (LSMCD), or atomic layer deposition (ALD). Patterning techniques refer to the deposition of material or photoresist, patterning, exposure, development, etching, cleaning, and/or removal of the material or photoresist as required in forming a described pattern, structure, or opening. Exemplary examples of patterning techniques may include wet etch photolithographic processes, dry etch photolithographic processes, or direct patterning processes. Planarization techniques refer to the process of removing surface topologies by flattening and smoothening uneven surfaces. An exemplary example of a planarization technique may include the chemical mechanical polishing/planarization (CMP) process.

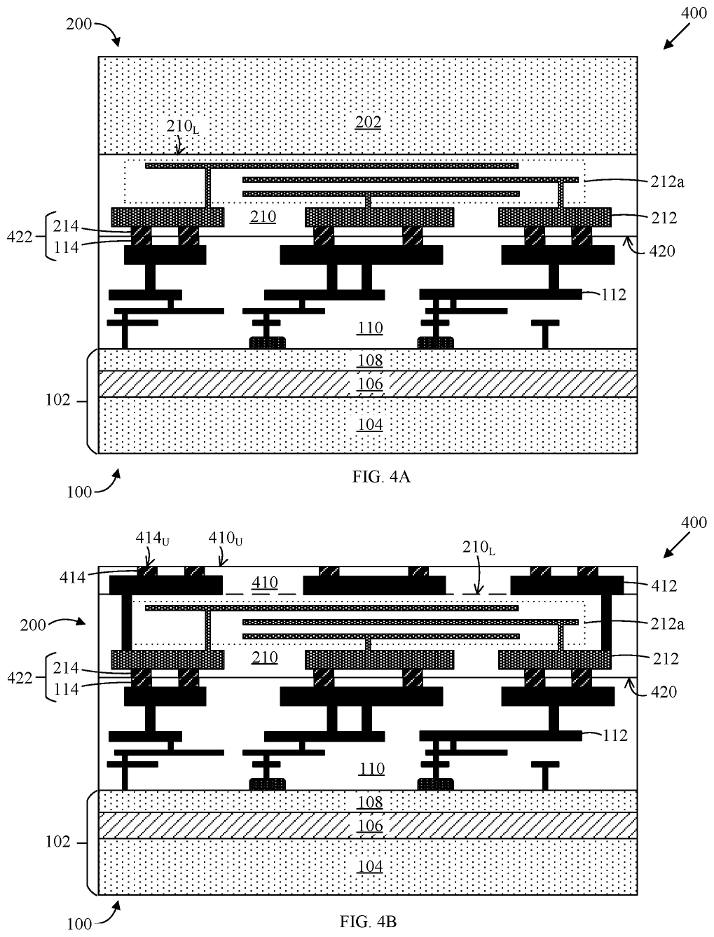

FIG. 2 is a cross-sectional view of a semiconductor device 200, according to an embodiment of the disclosure. The semiconductor device 200 may be in wafer or die form. The semiconductor device 200 may include a substrate 202 and an interlayer dielectric stack 210 over the substrate 202. The substrate 202 may be a bulk substrate, as illustrated, or a composite substrate that is similar to the substrate 102 in FIG. 1. One or more electronic components 212 may be arranged within the interlayer dielectric stack 210. The electronic components 212 may include a passive device 212a and interconnection structures over the passive device 212a; the interconnection structures may be in the form of electrically conductive lines and vias structures. The interconnection structures may be electrically connected to the passive device 212a. The passive device 212a may include resistors, capacitors, or inductors. In an embodiment of the disclosure, the semiconductor device 200 may not include any active devices.

The interlayer dielectric stack 210 may be formed from a plurality of dielectric layers (not shown) and may include an upper dielectric surface 210_{U} distal from the substrate 204 and a lower dielectric surface 210_{L} proximate, or in contact with, the substrate 204. The interlayer dielectric stack 210 may include an electrically insulative material, for example, silicon dioxide, carbon-doped silicon oxide, tetraethoxysilane (TEOS), borophosphosilicate glass (BPSG), or undoped silicate glass (USG). In an embodiment of the disclosure, the interlayer dielectric stack 210 may be preferred to have the same electrically insulative material as the interlayer dielectric stack 110 of the semiconductor device 100 in FIG. 1.

The semiconductor device 200 may further include conductive plugs 214 within the interlayer dielectric stack 210. The conductive plugs 214 may be arranged over and electrically connected to the electronic components 212, such as the interconnection structures. The conductive plugs 214 may serve as bonding structures to other wafers and/or dies for a stacked structure. The conductive plugs 214 may include a metallic material, for example, copper, aluminum, or alloys thereof. In an embodiment of the disclosure, the conductive plugs 214 may be preferred to have the same metallic material as the conductive plugs 114 of the semiconductor device 100 in FIG. 1.

The conductive plugs 214 may include an upper conductive surface 214_{U}, and the upper conductive surfaces 214_{U} of the conductive plugs 214 and the upper dielectric surface 210_{U} of the interlayer dielectric stack 210 may define a stacking interface 216, upon which other wafers and/or dies may be stacked on the semiconductor device 200. Even though FIG. 2 illustrates the upper dielectric surface 210_{U} and the upper conductive surfaces 214_{U} to be substantially coplanar, the upper conductive surfaces 214_{U} of the conductive plugs 214 may be dished below the upper dielectric surface 210_{U}. Additionally, the conductive plugs 214 are designed to be aligned with the conductive plugs 114 of the semiconductor device 100 in FIG. 1.

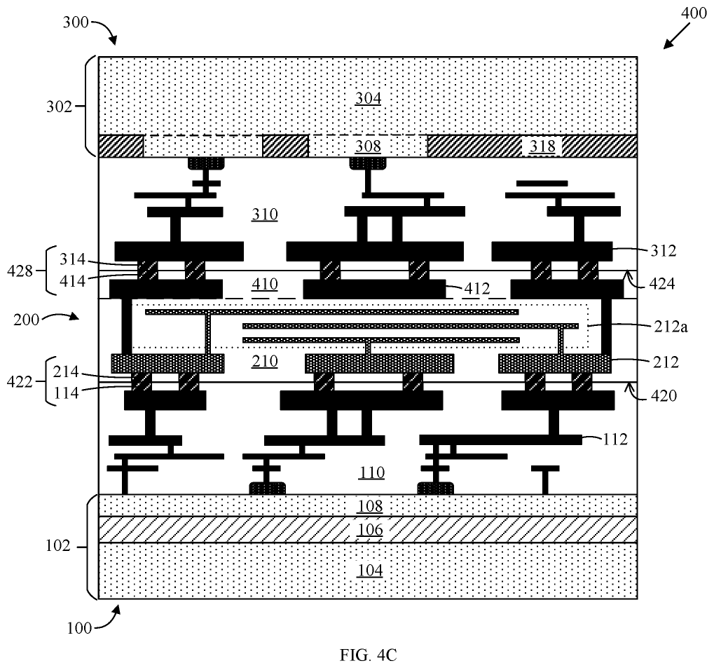

FIG. 3 is a cross-sectional view of a semiconductor device 300, according to an embodiment of the disclosure. The semiconductor device 300 may be in wafer or die form. The semiconductor device 300 may include a substrate 302. The substrate 302 may include a bulk layer 304 and an active layer 308 over the bulk layer 304; the transition of the active layer 308 to the bulk layer 304 is diagrammatically illustrated by a dashed line for purposes of illustration. The active layer 308 may be a doped portion of the substrate 302 while the bulk layer 304 may be undoped or doped to a dopant concentration lower than the active layer 308. Alternatively, the substrate 302 may be a composite substrate, similar to the substrate 102 of the semiconductor device 100 in FIG. 1, and the active layer 308 may be synonymous with the semiconductor layer 108 in the semiconductor device 100. The active layer 308 may be discontinuous, including isolation structures 318 separating each active layer portion 308 from an immediately adjacent active layer portion 308. The isolation structures 318 may include an electrically insulative material, for example, silicon dioxide or aluminum oxide. Alternatively, the active layer 308 may be continuous, similar to the semiconductor layer 108 in the semiconductor device 100.

The semiconductor device 300 may further include an interlayer dielectric stack 310 over the substrate 302. One or more electronic components 312 may be arranged within the interlayer dielectric stack 310, and the electronic components 312 may include active devices and interconnection structures in the form of conductive lines and vias structures. The electronic components 312 may, additionally or optionally, include passive devices.

The interlayer dielectric stack 310 may be formed from a plurality of dielectric layers (not shown) and may include an upper dielectric surface 310_{U}. The interlayer dielectric stack 310 may include an electrically insulative material, for example, silicon dioxide, carbon-doped silicon oxide, tetraethoxysilane (TEOS), borophosphosilicate glass (BPSG), or undoped silicate glass (USG). In an embodiment of the disclosure, the interlayer dielectric stack 310 may be preferred to have the same electrically insulative material as the interlayer dielectric stack 210 of the semiconductor device 200 in FIG. 2.

The semiconductor device 300 may further include conductive plugs 314 within the interlayer dielectric stack 310. The conductive plugs 314 may be electrically connected to the electronic components 312, such as the interconnection structures. The conductive plugs 314 may serve as bonding structures to other wafers and/or dies for a stacked structure. The conductive plugs 314 may include a metallic material, for example, copper, aluminum, or alloys thereof.

The conductive plugs 314 may include an upper conductive surface 314_{U}, and the upper conductive surfaces 314_{U} of the conductive plugs 314 and the upper dielectric surface 310_{U} of the interlayer dielectric stack 310 may define a stacking interface 316, upon which other wafers and/or dies may be stacked on the semiconductor device 300. Even though FIG. 3 illustrates the upper dielectric surface 310_{U} and the upper conductive surfaces 314_{U} to be substantially coplanar, the upper conductive surfaces 314_{U} of the conductive plugs 314 may be dished below the upper dielectric surface 310_{U}. Although FIG. 3 only illustrates four conductive plugs 314, the number of conductive plugs 314 may vary according to the design requirements of the stacked semiconductor structure that will be ultimately formed using the semiconductor device 300.

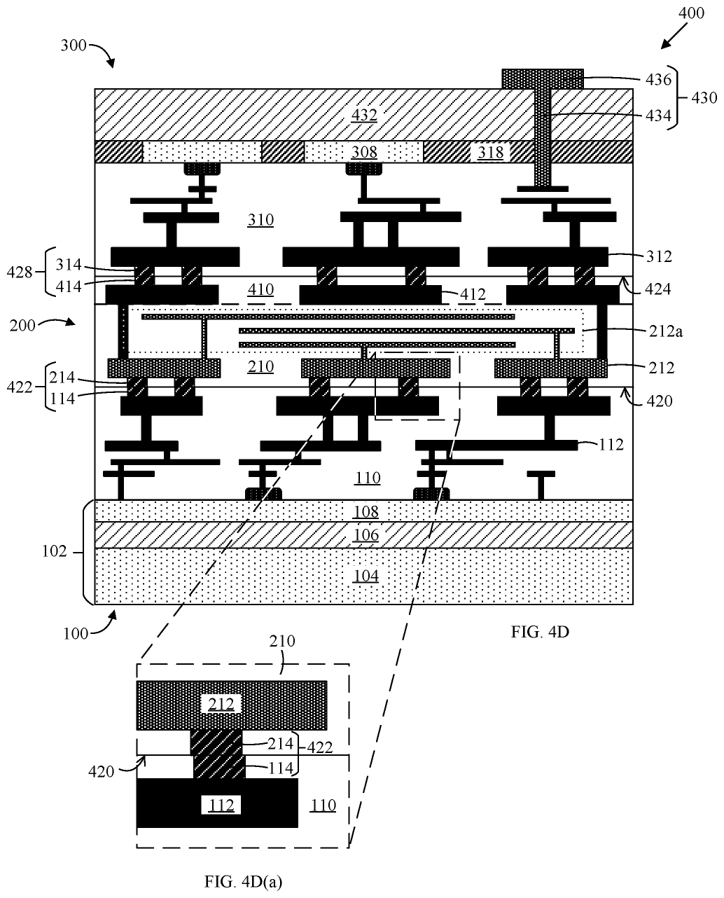

FIGS. 4A to 4D are cross-sectional views, depicting successive stages of manufacturing a stacked semiconductor structure 400, according to an embodiment of the disclosure. The stacked semiconductor structure 400 may be a stacked structure that comprises three dimensions (3D). Certain structures may be fabricated, for example, using known processes and techniques, and specifically disclosed processes and methods may be used to achieve individual aspects of the present disclosure. The below-described order for the method of forming the stacked semiconductor structure 400 is intended to be illustrative, and the method is not limited to the specifically described order unless otherwise specifically stated.

Referring to FIG. 4A, the semiconductor device 200 in FIG. 2 may be inverted and stacked on the semiconductor device 100 in FIG. 1, for example, the semiconductor device 100 may be at a first level and the semiconductor device 200 may be at a second level vertically above the first level. The interlayer dielectric stack 110 of the semiconductor device 100 may be in contact with the interlayer dielectric stack 210 of the semiconductor device 200 such that their respective stacking interfaces 116, 216 adjoin at a bonding interface 420. The bonding interface 420 may extend across the stacked semiconductor structure 400.

The conductive plugs 214 of the semiconductor device 200 may also substantially align with the conductive plugs 114 of the semiconductor device 100. While FIG. 4A illustrates that the conductive plugs 114, 214 have similar dimensions, such as widths and heights, the conductive plugs 114, 214 can have different dimensions, as long as the conductive plugs 114, 214 substantially overlap after stacking of the two semiconductor devices 100, 200.

The semiconductor devices 100, 200 may be permanently bonded through a hybrid bonding technique. The term “hybrid bonding” refers to the bonding between the wafers and/or dies that may be achieved through dielectric-to-dielectric bonds and metal-to-metal bonds that are formed between two surfaces, for example, between the stacking interfaces 116, 216 of the semiconductor devices 100, 200, respectively. The hybrid bonding technique may include a combination of molecular bonding and metallic bonding to achieve permanent bonding. During the bonding process, the initial bond occurs at the dielectric-to-dielectric interface, i.e., the upper dielectric surfaces 110_{U}, 210_{U} of the semiconductor devices 100, 200. Van der Waals interactions at the dielectric-to-dielectric interface “pull” the semiconductor devices 100, 200 together by forming dielectric-to-dielectric molecular bonds. A thermal anneal technique may be subsequently performed, fusing the conductive plugs 114, 214 of the semiconductor devices 100, 200 by forming metal-to-metal bonds through metal diffusion. The fused conductive plugs 114, 214 may serve as contacts 422 between the semiconductor devices 100, 200, and the contacts 422 may be ohmic. The contacts 422 enable electrical connections between the semiconductor device 100 and the semiconductor device 200.

As mentioned above, it may be preferred that the electrically insulative material of the respective interlayer dielectric stacks 110, 210 of the semiconductor devices 100, 200 include the same electrically insulative material. This would ensure that the interlayer dielectric stacks 110, 210 of both semiconductor devices 100, 200 are compatible with each other, resulting in the formation of strong dielectric-to-dielectric bonds at the bonding interface 420. Similarly, the conductive plugs 114, 214 are also preferred to have the same metallic material to form strong metal-to-metal bonds at the bonding interface 420.

FIG. 4B illustrates a cross-sectional view of the stacked semiconductor structure 400, after forming interconnection structures 412 and conductive plugs 414 on the semiconductor device 200, according to an embodiment of the disclosure. The substrate 202 of the semiconductor device 200 may be removed using a removal technique, as such a mechanical grinding process, which also may be referred to as a backgrinding process. The lower dielectric surface 210_{L} (now inverted to be facing in an upward orientation) of the interlayer dielectric stack 210 may be exposed after the removal of the substrate 202.

A dielectric layer 410 may be deposited over the lower (inverted) dielectric surface 210_{L} of the interlayer dielectric stack 210 using a deposition technique, including a CVD process. The dielectric layer may include an upper dielectric surface 410_{U}. The dielectric layer 410 may be preferred to have the same electrically insulative material as the interlayer dielectric stack 210 of the semiconductor device 200. The interface between the dielectric layer 410 and the interlayer dielectric stack 210 is diagrammatically illustrated by a dashed line for purposes of illustration. The interconnection structures 412 and the conductive plugs 414 may be formed in the dielectric layer 410 using a plurality of techniques, at least including patterning and deposition techniques. The interconnection structures 412 may further extend into the interlayer dielectric stack 210 and electrically connect to the electronic components 212 of the semiconductor device 200, such as the interconnection structures. Even though FIG. 4B illustrates the upper dielectric surface 410_{U} and the upper conductive surfaces 414_{U} of the conductive plugs 414 to be substantially coplanar, the upper conductive surfaces 414_{U} of the conductive plugs 114 may be dished below the upper dielectric surface 410_{U}. In an embodiment of the disclosure, the conductive plugs 414 are designed to be aligned with the conductive plugs 314 of the semiconductor device 300 that will be subsequently stacked over the semiconductor device 200.

FIG. 4C illustrates a cross-sectional view of the stacked semiconductor structure 400, after stacking the semiconductor device 300 over the semiconductor device 200, according to an embodiment of the disclosure. The semiconductor device 300 may be inverted and stacked on the dielectric layer 410. The interlayer dielectric stack 310 and the conductive plugs 314 of the semiconductor device 300 may be in contact with the dielectric layer 410 and the conductive plugs 414, respectively, at a bonding interface 424. The bonding interface 424 may extend across the stacked semiconductor structure 400. A hybrid bonding technique may be performed to bond the semiconductor device 300 to the device stack including semiconductor devices 100 and 200. The conductive plugs 314,414 may be fused and may serve contacts 428 between the dielectric layer 410 and the semiconductor device 300; the contacts 428 may be ohmic. The contacts 428 enable electrical connections between the semiconductor device 300 and the device stack including semiconductor devices 100 and 200.

FIG. 4D illustrates a cross-sectional view of the stacked semiconductor structure 400, after forming a circuitry interconnection 430, according to an embodiment of the disclosure. At least a portion of the substrate 302 of the semiconductor device 300, such as the bulk layer 304, may be removed using a removal technique, including a mechanical grinding process, up to at most the active layer 308.

A dielectric layer 432 may be deposited over the active layer 308 using a deposition technique, including a CVD process. The dielectric layer 432 may serve as a capping layer to at least protect the active layer 308. The circuitry interconnection 430 may be electrically connected to the electronic components 312 in the semiconductor device 300, such as the interconnection structures. The dielectric layer 432 may include an electrically insulative material, for example, silicon dioxide or aluminum oxide, and may or may not include the same electrically insulative material as the isolation structures 318.

The circuitry interconnection 430 may include a via structure 434 and a pad structure 436. The via structure 434 may be arranged at least through the dielectric layer 432 and the pad structure 436 may be on the dielectric layer 432. The pad structure 436 may also be referred to as a bond pad. The via structure 434 may additionally extend through the isolation structure 318. The circuitry interconnection 430 may be formed on the dielectric layer 432 using a plurality of techniques, including patterning and deposition techniques. The circuitry interconnection 430 may enable the stacked semiconductor structure 400 to be electrically connected to external electronic components, including dies, wafers, and/or a printed circuit board. In an embodiment of the disclosure, the via structure 434 of the circuitry interconnection 430 only extends through an electrically insulative material, such as the dielectric layer 432 and the isolation structure 318, and does not extend through a semiconductor material.

FIG. 4D(a) illustrates a cross-sectional view of an enlarged portion of the stacked semiconductor structure 400, according to an embodiment of the disclosure. The enlarged portion illustrates the bonding interface 420 between the respective conductive plugs 114, 214 of the semiconductor device 100 and the semiconductor device 200. While it may be ideal to have a fully aligned connection between the conductive plugs 114, 214, it may be acceptable for the conductive plugs 114, 214 to have a horizontal offset as long as the conductive plugs 114, 214 overlap substantially.

As presented above, stacked semiconductor structures including a passive device and methods of forming the same are presented. The stacked semiconductor structure may include a top semiconductor device, a middle semiconductor device, and a bottom semiconductor device bonded together using a hybrid bonding technique. The top and bottom semiconductor devices may each include an active layer, an active device over the active layer, and an interconnection structure over the active device. The middle wafer may include a passive device and an interconnection structure over the passive device. The passive device may be arranged between and electrically connected to the interconnection structures of the top and bottom semiconductor devices. There is an absence of a crystalline semiconductor material between the top semiconductor device and the bottom semiconductor device. The stacked semiconductor structure may further include a circuitry interconnection electrically connected to the interconnection structure of the top semiconductor device, providing an electrical connection between the stacked semiconductor structure and external electronic components.

The stacked semiconductor structures may be formed by providing a bottom semiconductor device, a middle semiconductor device, and a top semiconductor device. The bottom semiconductor device may include a substrate, a first active layer in the substrate, a first interconnection structure over the first active layer, and a first conductive plug over the first interconnection structure. The middle semiconductor device includes a passive device, a second interconnection structure over the passive device, and a second conductive plug over the second interconnection structure. The top semiconductor device may include a second active layer, a third interconnection structure over the second active layer, and a third conductive plug over the third interconnection structure. The middle semiconductor device is bonded between the bottom semiconductor device and the top semiconductor device such that the passive device is arranged between and electrically connected to the interconnection structures of the top and bottom semiconductor devices.

The stacked semiconductor structure has advantageously eliminated the use of TSVs that negatively impact the electrical performances of the semiconductor devices due to the introduction of parasitic resistance and capacitance. The interconnection structures and circuitry interconnection are arranged through electrically insulative materials, such as interlayer dielectrics and dielectric capping layers, and are, therefore, smaller than typical TSVs and yet deliver better electrical performances.

The terms “top”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed by interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of features is not necessarily limited to those features but may include other features not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,” or “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of 90 degrees plus or minus a normal tolerance of the semiconductor industry.

While several exemplary embodiments have been presented in the above-detailed description of the device, it should be appreciated that a number of variations exist. It should further be appreciated that the embodiments are only examples, and are not intended to limit the scope, applicability, dimensions, or configuration of the device in any way. Rather, the above-detailed description will provide those skilled in the art with a convenient road map for implementing an exemplary embodiment of the device, it is understood that various changes may be made in the function and arrangement of features and methods of fabrication described in an exemplary embodiment without departing from the scope of this disclosure as set forth in the appended claims.

What is claimed is:

1. A semiconductor structure, comprising:
a substrate;
a first active layer in the substrate;
a second active layer vertically over the first active layer;
a first interconnection structure between the first active layer and the second active layer;
a second interconnection structure between the first interconnection structure and the second active layer;
a first interlayer dielectric stack between the first interconnection structure and the second interconnection structure; and
a passive device in the first interlayer dielectric stack.

2. The semiconductor structure of claim 1, wherein the passive device is electrically connected to the first interconnection structure and the second interconnection structure.

3. The semiconductor structure of claim 1, further comprising:
a second interlayer dielectric stack over the first active layer, and the first interconnection structure is in the second interlayer dielectric stack;
a third interlayer dielectric stack between the second interlayer dielectric stack and the second active layer, and the second interconnection structure is in the third interlayer dielectric stack; and
the first interlayer dielectric stack is between the second interlayer dielectric stack and the third interlayer dielectric stack.

4. The semiconductor structure of claim 3, wherein the first interlayer dielectric stack is in contact with the second interlayer dielectric stack.

5. The semiconductor structure of claim 4, wherein a crystalline semiconductor material is absent between the second interlayer dielectric stack and the third interlayer dielectric stack.

6. The semiconductor structure of claim 4, further comprising:
a first active device in the second interlayer dielectric stack; and
a second active device in the third interlayer dielectric stack, and the passive device is between the first active device and the second active device.

7. The semiconductor structure of claim 4, further comprising a first contact extending between the first interlayer dielectric stack and the second interlayer dielectric stack.

8. The semiconductor structure of claim 7, wherein the first contact includes a first conductive plug in the first interlayer dielectric stack and a second conductive plug in the second interlayer dielectric stack.

9. The semiconductor structure of claim 8, wherein the first conductive plug is horizontally offset from the second conductive plug.

10. The semiconductor structure of claim 8, wherein the first interlayer dielectric stack and the second interlayer dielectric stack each comprise a dielectric surface, and the dielectric surface of the first interlayer dielectric stack adjoins the dielectric surface of the second interlayer dielectric stack at a bonding interface.

11. The semiconductor structure of claim 10, wherein the first conductive plug and the second conductive plug each comprise a conductive surface, and the conductive surface of the first conductive plug adjoins the conductive surface of the second conductive plug at the bonding interface.

12. The semiconductor structure of claim 11, wherein the bonding interface extends across the semiconductor structure.

13. The semiconductor structure of claim 7, further comprising:
a dielectric layer between the first interlayer dielectric stack and the third interlayer dielectric stack; and
a second contact extending between the dielectric layer and the third interlayer dielectric stack.

14. The semiconductor structure of claim 1, further comprising:
a dielectric layer, wherein the second active layer is between the dielectric layer and the second interconnection structure; and
a circuitry interconnection extending through the dielectric layer and electrically connected to the second interconnection structure.

15. The semiconductor structure of claim 14, wherein the circuitry interconnection comprises a via structure extending through the dielectric layer and a pad structure on the dielectric layer.

16. A method of forming a semiconductor structure, comprising:
forming a first semiconductor device including a substrate, a first active layer in the substrate, a first interconnection structure over the first active layer, and a first conductive plug over the first interconnection structure;
forming a second semiconductor device including a passive device, a second interconnection structure over the passive device, and a second conductive plug over the second interconnection structure;
forming a third semiconductor device including a second active layer, a third interconnection structure over the second active layer, and a third conductive plug over the third interconnection structure; and
forming a stacked structure including the third semiconductor device between the first semiconductor device and the second semiconductor device, wherein the passive device in the second semiconductor device is between and electrically connected to the first interconnection structure and the second interconnection structure.

17. The method of claim 16, further comprising:
stacking the third semiconductor device on the first semiconductor device to align the third conductive plug with the first conductive plug; and
performing a bonding technique to fuse the first conductive plug and the third conductive plug.

18. The method of claim 17, further comprising:
forming a dielectric layer on the third semiconductor device, wherein the dielectric layer comprises an upper dielectric surface;
forming a fourth interconnection structure in the dielectric layer electrically connected to the third interconnection structure; and
forming a fourth conductive plug in the dielectric layer electrically connected to the fourth interconnection structure, wherein the fourth conductive plug comprises an upper conductive surface, and the upper conductive surface is coplanar with the upper dielectric surface and forms a stacking interface.

19. The method of claim 18, further comprising:
stacking the second semiconductor device on the stacking interface, wherein the second conductive plug is aligned with the fourth conductive plug at the stacking interface.

20. The method of claim 19, further comprising performing a hybrid bonding technique to fuse the second conductive plug and the fourth conductive plug.
